(19) United States
(12) Patent Application Publication
(10) Pub. No.: US 2007/0128761 A1
(43) Pub. Date: Jun. 7, 2007

(54) Manufacturing Method of Solar Cell Element

(75) Inventors: Hiroto OWADA, Higashiomi-shi, Shiga (JP); Hajime ITO, Utsunomiya-shi, Tochigi (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION, Kyoto (JP)

(21) Appl. No.: 11/564,155

(22) Filed: Nov. 28, 2006

(30) Foreign Application Priority Data
Nov. 29, 2005 (JP) 2005-343731
Nov. 22, 2006 (JP) 2006-315439

(51) Int. Cl. H01L 21/00

(52) U.S. Cl. 438/98

(57) ABSTRACT

A manufacturing method includes the steps of disposing a base substance for a solar cell element inside a first chamber and then supplying a first gas to etch one principal surface of the base substance, thereby roughening the one principal surface while attaching an etch residue thereto; and disposing the base substance inside a second chamber and then supplying a second gas having lower reactivity than the first gas to convert the second gas into a plasma state, thereby removing the etch residue remaining on the one principal surface.

### BACKGROUND OF THE INVENTION

1. Field of the Invention

The present invention relates to a manufacturing method of a solar cell element, and to a manufacturing method of a solar cell element having the step of roughening at least a part of a base substance.

2. Description of the Background Art

Solar cells convert light energy such as solar light incident on a surface thereof into electric energy. In order to improve efficiency of this conversion into electric energy, various attempts have conventionally been made. One of the attempts is a technique such that a reduction in reflection of light irradiated on a surface of a substrate improves efficiency of the conversion into electric energy.

Principal solar cells are classified into crystal type, amorphous type and compound type in accordance with kinds of materials used. Among these, most of solar cells currently distributed on the market are crystalline silicon solar cells. These crystalline silicon solar cells are further divided into monocrystalline type and polycrystalline type. Monocrystalline silicon solar cells have a merit such that the quality of a substrate is so good as to facilitate achieving higher conversion efficiency, and on the contrary a demerit such that manufacturing costs of the substrate are high. By contrast, polycrystalline silicon solar cells have a demerit such that it is relatively difficult to achieve higher conversion efficiency, and nevertheless a merit such that the substrate can be manufactured at low costs. Recently, an improvement in the quality of a polycrystalline silicon substrate and an advancement in a cellularizing technique have allowed a conversion efficiency of approximately 18% to be accomplished on the research level also with regard to polycrystalline silicon solar cells.

On the other hand, polycrystalline silicon solar cells on the level of mass production, which can be manufactured at low costs and nevertheless are inferior to ones on the research level in conversion efficiency, have conventionally been distributed to the market and further in a growing demand in recent years while environmental issues are being reported. Higher conversion efficiency has been requested together with the achievement of a thinner substrate.

In a case of forming a solar cell element by using a silicon substrate, a surface of the substrate is etched with an alkali aqueous solution such as sodium hydroxide to form a fine uneven surface structure on the surface of the substrate, so that reflection thereon can be reduced to some degree.

For example, in a case of using a monocrystalline silicon substrate of (100) plane in a plane direction, such a method allows a pyramidal uneven surface structure to be uniformly formed on a surface of a substrate. However, in a case of forming a solar cell element with a polycrystalline silicon substrate, the problem is that etching with alkali aqueous solution does not allow an uneven surface structure to be uniformly formed and does not allow the total reflectance to be efficiently reduced by reason of depending on a plane direction of the crystal.

In order to solve such a problem, it is proposed that an uneven surface structure be formed on one principal surface of a substrate by using a reactive ion etching (RIE) method in a case of forming a solar cell element with a polycrystalline silicon substrate (for example, refer to Japanese Patent Application Laid-Open No. 9-102625 (1997)).

Silicon is basically vaporized in dry etching, a part of which is not vaporized up and silicon molecules are adsorbed to each other to remain as an etch residue on a surface of a substrate. Based on this fact, with accelerating a rate that the etch residue, which is caused by etching the surface of a substrate by reactive ion etching method and similar dry etching method, and therefore whose principal component coincides substrate materials, reattaches to the surface of a substrate, the surface of a substrate can be roughened by using this etch residue as a mask of the etching.

Even in a case of using a polycrystalline silicon substrate, the use of this method allows etching hardly susceptible to a plane direction thereof and allows an uneven surface structure comprising many fine projections to be uniformly formed on a surface thereof That is, even in a case of a solar cell element using polycrystalline silicon, the use allows reflectance to be reduced more efficiently, whereby conversion efficiency can be improved.

However, in a case where a surface of a base substance (a substrate) is roughened by this dry etching method, many etch residues are dispersed and attached to the surface of a base substance, so that the following problems are caused. For example, the remaining of these etch residues on the base substance brings a possibility of causing unevenness in forming an antireflection film as the post-process. Also, the etch residues shield the light on a receiving surface of a solar cell element, so that conversion efficiency of the solar cell is decreased.

Then, ultrasonic treatment in water has conventionally been performed in order to remove these etch residues. In this method, with a tray on which a base substance is placed being immersed in water, ultrasonic waves are applied into water with an ultrasonic horn, thereby to remove the etch residues. For example, a method is publicly known such that a base substance is placed on a tray fixed to a belt or a chain for revolution, which tray is immersed in water and continuously passed through an ultrasonic horn unit to thereby remove the etch residues continuously (for example, refer to Japanese Patent Application Laid-Open No. 2003-273376).

FIGS. 4A, 4B and 4C are schematic views showing the change of state on a semiconductor substrate surface in a case of forming a surface uneven structure on the surface of a semiconductor substrate for a conventional solar cell element. FIG. 4A is a view showing state immediately after roughening the surface by dry etching. FIG. 4B is a view showing state after removing etch residues by ultrasonic treatment. FIG. 4C is a view showing state after performing hydrofluoric acid treatment following the ultrasonic treatment. As shown in FIG. 4A, the etching is avoided below a place masked by an etch residue 121, so that a fine projection portion 123 is formed on a semiconductor substrate surface 101 after performing dry etching. In other words, it can also be conceived that the etch residue 121 attaches onto the fine projection portion 123 through a pillar portion 122.

When etch residue removal is performed on the semiconductor substrate surface 101 in such a state by using ultrasonic waves as described above, impact force caused by ultrasonic irradiation removes the etch residue and yet the impact force also damages the semiconductor substrate surface 101 including the projection portion 123, so that the problem is that a microcrack 123a is caused in the projection portion 123 as shown in FIG. 4B, a chip 123b is caused in the projection portion 123 at a stage of the following hydrofluoric acid treatment as shown in FIG. 4C, or crack/chip (not shown in the FIGS) are further caused also on the semiconductor substrate surface 101. This decreases the yield of the step of manufacturing a solar cell element.

One of the reasons why a base substance is damaged in etch residue removal by using ultrasonic waves is that the magnitude of impact force during the etch residue removal. The reason therefor is that cavitation bubbles are produced in applying ultrasonic waves into water and repeatedly expanded/compressed, the collapse of which causes a field of high temperature and pressure to be locally formed. It is conceived that as high impact force as several GPa is caused in this collapse of the bubbles and removes the etch residue, and yet damages the base substance greatly by reason of being also applied thereto.

The ultrasonic treatment is performed by immersing a tray on which a base substance is placed in water, and minute bubbles interposing between the base substance and the tray are broken through oscillation by irradiating ultrasonic waves, so that the base substance sticks to the tray without gaps after the treatment and frequently can not easily be peeled thereof. Thus, the problem is also that the base substance is damaged in being peeled off the tray. This has been a nonnegligible problem in the development of a solar cell element in recent years when thinning of a semiconductor substrate is an important technical issue. It is requested that a method of removing the etch residue instead of ultrasonic treatment be established also from this point.

### SUMMARY OF THE INVENTION

The present invention relates to a manufacturing method of a solar cell element and to a manufacturing method of a solar cell element having the step of roughening at least a part of a base substance.

According to the present invention, a manufacturing method of a solar cell element comprises the following steps of (a) disposing a base substance for a solar cell element inside a first chamber and then supplying a first gas to etch one principal surface of the base substance, thereby roughening the one principal surface while attaching an etch residue thereto; and (b) disposing the base substance inside a second chamber and then supplying a second gas having lower reactivity than the first gas to convert the second gas into a plasma state, thereby removing the etch residue remaining on the one principal surface.

Thus, the etch residue on the base substance surface, caused by the roughening step, can preferably be removed while damage to the base substance is reduced. That is, while suppressing the occurrence of microcracks in a projection portion formed at the roughening step, the manufacturing method can remove the etch residue from a surface of the base substance such as a semiconductor substrate to form a surface uneven structure. Thus, cracks and chips are restrained from occurring on a surface of the base substance in accordance with removal of the etch residue. The etch residue is so preferably removed as to be capable of restraining a deterioration in conversion efficiency of a solar cell element for the reason that incident light is shielded by the etch residue to shade a receiving surface. That is, the removal can restrain deterioration in properties of a solar cell element due to damage to the base substance, and additionally improve the yield of a solar cell element.

Accordingly, the object of the present invention is to provide a manufacturing method of a solar cell element, in which damage to the base substance is restrained in removing the etch residue.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing an example applied to a manufacturing method of a solar cell element according to the present invention.

FIG. 2 is a view showing reactive ion etching equipment as an example of dry etching equipment to be used in roughening a surface of a semiconductor substrate.

FIGS. 3A, 3B and 3C are enlarged schematic views showing appearance of structural change in a minute portion on a surface of a semiconductor substrate by performing the roughening step and the residue removing step. FIG. 3A is a view showing state immediately after roughening a surface of the semiconductor substrate. FIG. 3B is a view showing state of a surface of the semiconductor substrate from which etch residue was removed by the residue removing step. FIG. 3C is a view showing state after performing hydrofluoric acid treatment following the removal of the etch residue by the residue removing step.

FIGS. 4A, 4B and 4C are schematic views showing the change of state on a semiconductor substrate surface in a case of forming a surface uneven structure on the surface of a semiconductor substrate for a conventional solar cell element. FIG. 4A is a view showing state immediately after roughening the surface by dry etching. FIG. 4B is a view showing state after removing etch residues by ultrasonic treatment. FIG. 4C is a view showing state after performing hydrofluoric acid treatment following the ultrasonic treatment.

### DESCRIPTION OF THE PREFERRED EMBODIMENTS

A manufacturing method of a solar cell element according to embodiments of the present invention is hereinafter detailed based on accompanying figures. A case of using a semiconductor substrate as a base substance of a solar cell element is herein described, which base substance is not limited to a semiconductor substrate but a base substance made of glass, metal, plastics or resin may be used. A case where a shape of a base substance is tabular is described, which shape is not merely tabular but also optionally globular in embodiments, for example.

<Constitution Outline of Solar Cell Element>

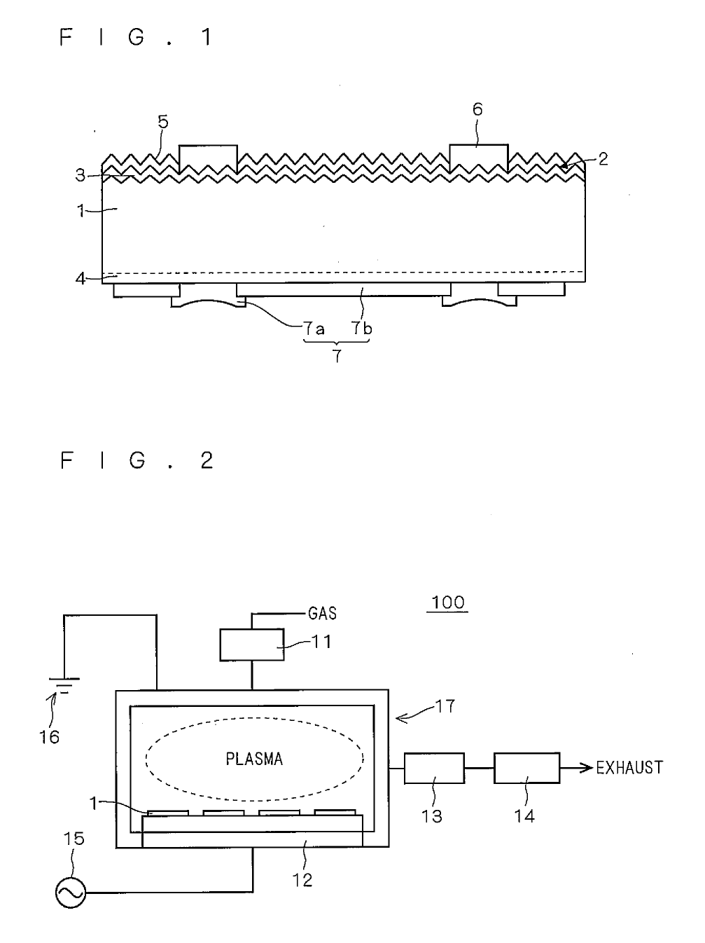

FIG. 1 is a cross-sectional schematic view roughly showing the constitution of a solar cell element 10 formed by using a manufacturing method of a solar cell element according to the embodiments. As shown in FIG. 1, the solar cell element 10 is composed principally of a semiconductor substrate 1 having a surface uneven structure 2 on the front side (the receiving surface side), a front impurity diffusion layer 3 formed on the front side of the semiconductor substrate 1, a back impurity diffusion layer (BSF) 4 formed on the back side of the semiconductor substrate 1, an antireflection film 5, a front electrode 6, and a back electrode 7 comprising a takeout electrode 7a and a collecting electrode 7b.

The polarity of the semiconductor substrate 1 may be either of p-type and n-type, and a case where a p-type silicon substrate such that B (boron) is conveniently included as a doping impurity element in Si (silicon) is used as the semiconductor substrate 1 is described in the embodiments.

Examples of an ingot to be used for cutting out the semiconductor substrate 1 include a monocrystalline silicon ingot made by methods such as CZ method, FZ method and EFG method, and a polycrystalline silicon ingot cast by a cast method. Polycrystalline silicon can be mass-produced and is extremely more advantageous than monocrystalline silicon in view of manufacturing costs.

The ingot formed by the above-mentioned method is cut into a size of approximately 10 cm×10 cm or 15 cm×15 cm, and sliced into a thickness of 300 μm or less by using a wire-saw to obtain the semiconductor substrate 1.

With regard to doping of an impurity element into the semiconductor substrate 1, a simple substance of an impurity element to be doped may be included by a proper amount in materials for manufacturing a semiconductor substrate during the manufacture of the ingot, or semiconductor materials for adding with a certain doping concentration may be added by a proper amount to materials for manufacturing a semiconductor substrate, not doped with impurities, and then melted to manufacture a semiconductor ingot having a predetermined doping concentration.

The surface uneven structure 2 for effectively taking in incident light without reflection is formed on the front side of the semiconductor substrate 1. The surface uneven structure 2 is formed, for example, in such a manner that the semiconductor substrate 1 is placed in a predetermined chamber and vacuum-pumped to then introduce gas thereinto and retain at a certain pressure, and plasma is generated by impressing RF electric power on an electrode placed in the chamber, thereby to etch a surface of the semiconductor substrate 1 by ions and radicals in the plasma.

It is desirable that the aspect ratio (height/width) of this surface irregular structure 2 be in a range of 0.1 to 2. An aspect ratio of more than 2 brings a problem such that the surface irregular structure 2 is broken at the process of manufacturing a solar cell element to increase leak current in a case of forming a solar cell element, whereby favorable output characteristics are not obtained. An aspect ratio of less than 0.1 brings a problem such that the average reflectance of light with a wavelength of 500 to 1000 nm is approximately 25% and reflectance on a surface of the semiconductor substrate 1 is increased.

The formation of this surface irregular structure 2 is detailed later.

The front impurity diffusion layer 3 is formed on the front side of the semiconductor substrate 1 on which the surface uneven structure 2 as described above is formed. For example, in a case of forming the front impurity diffusion layer 3 by diffusing n-type impurities, the front impurity diffusion layer 3 can be formed by diffusing reverse conducting semiconductor impurities on the front side of the semiconductor substrate 1 by vapor phase diffusion method with POCl₃, application diffusion method with P₂O₅ and ion-implantation method of directly diffusing p⁺ ions. A hydrogenated amorphous silicon film and a crystalline silicon film including a microcrystalline silicon film may be formed by using thin film techniques and conditions.

This front impurity diffusion layer 3 is formed at a depth of approximately 0.2 to 0.5 μm. Thereafter, for example, the immersion in chemicals such as dilute hydrofluoric acid solution allows a surface of the semiconductor substrate 1 to be cleansed and phosphate glass formed on the surface to be removed.

In a case where a diffusion layer except the front impurity diffusion layer 3 is formed on the back side of the semiconductor substrate 1 by the above-mentioned technique, the portions other than the front impurity diffusion layer 3 are removed and then the semiconductor substrate is washed in pure water. This removal method is preferred to include the following manner: a film having resistance to hydrofluoric acid is applied onto the front side of the semiconductor substrate 1, a diffusion layer except for the receiving surface side of this semiconductor substrate 1 is etched away by using mixed solution of hydrofluoric acid and nitric acid, and thereafter the film having resistance to hydrofluoric acid applied onto the front side is removed.

The antireflection film 5 is further formed on the front side of the semiconductor substrate 1. Plasma CVD method, deposition method and sputtering method can be used for forming this antireflection film 5, which is typically formed by using plasma CVD method.

Examples of materials to be used for the antireflection film 5 include Si₃N₄ film, TiO₂ film, SiO₂ film, MgO film, ITO film, SnO₂ film and ZnO film. Generally, Si₃N₄ film is preferably used by reason of rendering passivation effect. For example, by shifting mixed gas of silane and ammonia as source gas to plasma by RF or microwaves, thereby to produce Si₃N₄, it is implemented to form the antireflection film 5.

It is desirable that the back impurity diffusion layer 4 in which conductive semiconductor impurities are diffused at high concentration be formed on the back side of the semiconductor substrate 1. This back impurity diffusion layer 4 forms an internal electric field on the back side of the semiconductor substrate 1 to prevent a decrease in efficiency due to recombination of carriers at the near of the back side of the semiconductor substrate 1. B (boron) and Al (aluminum) can be used as an impurity element. The impurity element concentration on the back side of the semiconductor substrate 1 is increased to obtain p⁺ type, whereby ohmic contact can be obtained between it and the after-mentioned back electrode 7.

The back impurity diffusion layer 4 can be formed by using a thermal diffusion method of diffusing B from BBr₃ (boron tribromide) as a diffusion source by heating to a temperature of approximately 800 to 1100° C., and a method such that Al paste comprising Al powder, organic solvent and binder is applied onto the back side of the semiconductor substrate 1 by a printing process, and thereafter heat-treated (fired) at a temperature of approximately 600 to 850° C., thereby to diffuse Al toward the semiconductor substrate 1.

In a case of forming the back impurity diffusion layer 4 by a thermal diffusion method, it is desirable that a diffusion barrier such as an oxide film be previously formed in the front impurity diffusion layer 3 already formed. In a case of using a method of printing and firing Al paste, the merit is that a desirable diffusion layer can be formed only on a printing surface, and additionally even in a case where an n-type reverse conducting diffusion layer is formed also on the back side simultaneously with the formation of the front impurity diffusion layer 3 as already described, the n-type reverse conducting diffusion layer need not be removed. The Al layer formed by firing is not removed but can be utilized directly as the collecting electrode 7b of the back electrode.

The front electrode 6 and the back electrode 7 are formed on the front side and the back side of the semiconductor substrate 1, respectively. Examples of a manufacturing method of these electrodes include a film forming process of forming a thick film by a printing process with the use of paste including metal powder principally such as Ag, glass frit, organic solvent and binder, and a film forming process by using vacuum processes such as sputtering method and deposition method.

Materials for the front electrode 6 are not particularly limited, and it is desirable to use materials including at least one kind of low resistance metals such as Ag, Cu and Al. Materials for the back electrode 7 also are not particularly limited, and it is desirable to use metal consisting essentially of Ag with high reflectance against silicon in a case of using silicon for the semiconductor substrate 1. These electrode materials are not limited to one kind but it is possible that plural materials are mixed in accordance with purposes and electrode layers of different compositions are laminated. It is optional to use metal consisting essentially of Ag for the takeout electrode 7a and metal consisting essentially of Al for the collecting electrode 7b.

The pattern of electrode materials is preferred to be a pattern generally used for collecting from a solar cell element. For example, in a case of the front electrode 6, it is preferred to be a general comb-shaped pattern. In addition, any material and shape can be used for a mask for making the electrode into a predetermined shape if not greatly affect the internal atmosphere. From the viewpoint of processability in accordance with the electrode pattern, it is simple and easy that the mask is made of metal.

<Formation of Surface Irregular Structure>

Next, the formation of the surface uneven structure 2 is detailed, which is characteristic of a manufacturing method of a solar cell element according to the embodiments.

In a manufacturing method of a solar cell element according to the embodiments, the above-mentioned surface uneven structure 2 is formed by sequentially performing the roughening step of roughening a surface of the semiconductor substrate 1 by etching and the residue removing step of removing an etch residue attached to the surface by causing a gas in a plasma state to impinge thereon.

First, the roughening step of roughening a surface of the semiconductor substrate 1 by etching is performed in a manner to be described below.

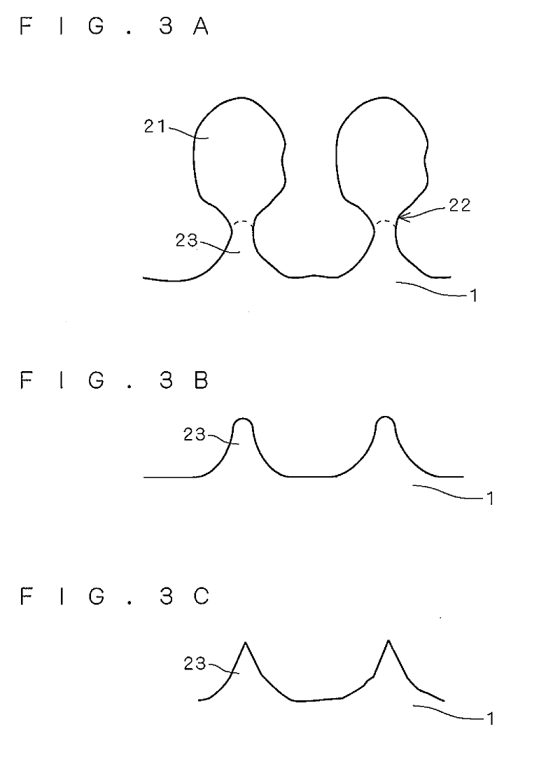

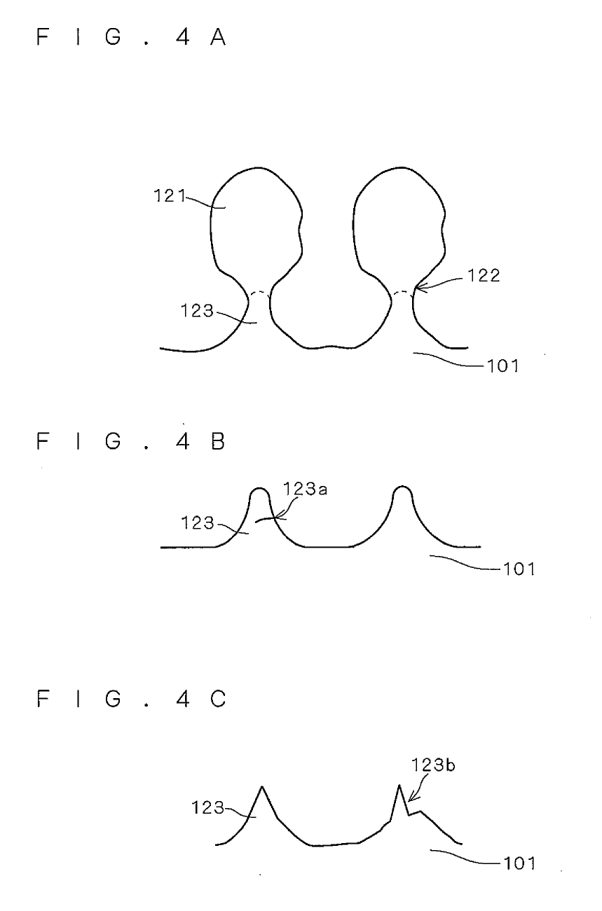

FIG. 2 is a view showing reactive ion etching equipment 100 as an example of dry etching equipment to be used in roughening a surface of the semiconductor substrate 1. FIGS. 3A, 3B and 3C are enlarged schematic views showing appearance of structural change in a minute portion on a surface of the semiconductor substrate 1 by performing the roughening step and the residue removing step.

As shown in FIG. 2, the reactive ion etching equipment 100 is provided principally with a mass flow controller 11, an RF electrode 12, a pressure regulator 13, a vacuum pump 14, an RF power supply 15, a ground 16 and a chamber 17.

The roughening step is performed as below: the semiconductor substrate 1 is placed at the top of the RF electrode 12, the inside of the chamber 17 grounded by the ground 16 is sufficiently vacuumed with the vacuum pump 14, etching gas (a first gas) at a predetermined flow rate is thereafter introduced into the chamber 17 by the mass flow controller 11, with regulated to a predetermined pressure by the pressure regulator 13, and RF electric power is impressed from the RE power supply 15 on the RF electrode 12 to generate a plasma state by exciting an decomposing the etching gas. Herewith, a surface of the semiconductor substrate 1 is etched by the generated ions and radicals.

Gas including a group 17 element which has a strong etching action upon the semiconductor substrate 1, especially high chemical reactivity with the semiconductor substrate 1, is used as the etching gas (a first gas). The group 17 element is defined as an element classified into the group 17 based on the IUPAC inorganic chemistry nomenclature revised in 1989, employing serial numbers 1 to 18 for group numbers.

For example, in such a condition that the reaction pressure is set at approximately 5 to 15 Pa while letting chlorine-based gas, fluorine-based gas and oxygen gas flow as the etching gas by predetermined flow rates, and RF electric power is impressed at approximately 5 to 10 kW, a surface of the semiconductor substrate 1 is roughened by generated plasma.

More specifically, a preferable example thereof is such that the reaction pressure is set at 7 Pa while introducing chlorine (Cl₂), oxygen (O₂) and trifluoromethane (CHF₃) into the chamber 17 at a flow ratio of 1:6:4, RF electric power for generating plasma is set at 5 kW, and etching time is set for approximately 5 minutes.

The first gas, however, is not limited to chlorine (CO₂) and trifluoromethane (CHF₃) but may be a combination of other gases, for example, HCl and ClF₃ as chlorine-based gas, and F₂, NF, CF₄, C₂F₆, C₃F₈, ClF₃ and SF₆ as fluorine-based gas.

FIG. 3A is a view showing state immediately after roughening a surface of the semiconductor substrate 1 in such a manner. A structure such that an etch residue 21 attaches onto a projection portion 23 through a pillar portion 22, as shown in FIG. 3A, is formed minutely and uniformly on a surface of the semiconductor substrate 1 immediately after being subjected to the roughening step.

When a surface of the semiconductor substrate 1 is etched, the components of the surface basically remove therefrom. Some of the components, however, are unable to remove but remain on the surface of the semiconductor substrate 1, and some of the removed substances adsorb on the surface of the semiconductor substrate again. These substances become the etch residue 21. Thus, the structure as shown in FIG. 3A is formed. In the roughening step, the roughening of the surface of the semiconductor substrate 1, which leads to the formation of the surface uneven structure 2 by extension, is realized by intentionally reattaching the etch residue 21 composed predominantly of the etched material of the semiconductor substrate 1 to the surface of the semiconductor substrate 1 and utilizing it as a mask of etching.

In this way, the surface of the semiconductor substrate 1 is certainly roughened, when dry etching is performed on the conditions that the etch residue 21 comprising the same materials as the semiconductor substrate 1 reattaches to the surface of the semiconductor substrate 1, with gas, reaction pressure and RF electric power being properly regulated. On the contrary, even though dry etching is performed on the conditions that the etch residue 21 as shown in FIG. 3A does not remain on the surface of the semiconductor substrate 1, i.e. on the conditions that the etch residue cannot be used as the etching mask, the roughening and the formation of the surface uneven structure 2 subsequent thereto are difficult because a recessed portion formed by etching the substrate surface has a flat inner bottom surface.

In reactive ion etching (RIE) method, etching proceeds by collision of ions generated in the chamber with the surface of the semiconductor substrate 1 and reaction between radicals generated therein and the surface. Alternatively, the roughening step may be carried out by using a method such that etching proceeds with reaction between the radicals and the surface of the semiconductor substrate 1 without the aforementioned collision of the ions. The occurrence principle of plasma in both of the methods is basically the same; however, active species contributing to etching are different. In either of the methods, however, the distribution of kinds of active species (ion and radical) acting on the semiconductor substrate 1 varies with chamber structure, electrode structure or generation frequency.

Next, the residue removing step for removing the etch residue 21 remaining on the semiconductor substrate 1 subsequent to such roughening step is performed.

The residue removing step is performed by using a second gas having low reactivity, different from the first gas used in the roughening step. Specifically, the semiconductor substrate 1 subject to the roughening step is placed in a predetermined chamber and then the second gas is converted into a plasma state in the chamber. At least one of thus generated gas molecules, ions and radicals composing the second gas collides with the etch residue 21 (in particular, the fragile pillar portion 22) and breaks this. This is why the removal of the etch residue 21 is realized. FIG. 3B is a view showing state of the surface of the semiconductor substrate 1 from which the etch residue 21 was removed by the residue removing step. As shown in FIG. 3B, the performance of the residue removing step renders the surface uneven structure 2 consisting the projection portion 23 on the surface of the semiconductor substrate 1.

Here, gas comprising one or more elements among elements belonging to the groups 1 to 16 and 18 is principally used as the second gas. The element belonging to the groups 1 to 16 and 18 is defined as an element classified into any of the groups 1 to 16 and 18 based on the IUPAC inorganic chemistry nomenclature revised in 1989, employing serial numbers for group numbers that is, the second gas mainly includes other than reactive gas principally consisting an element belonging to the group 17, such as Ruorine-based etching gas.

The second gas having low reactivity implies a gas which has a weaker etching action upon the semiconductor substrate 1 resulting from activated species generated when the gas is converted into a plasma state than the first gas, that is, which is substantially more inert than the first gas. Accordingly, even in a case where gas of the same kind as the first gas is mixed therewith, it is possible to use it as the second gas if it does not have the etching action and yet has the residue removing action for the reason that the mixture ratio is different.

In the residue removing step, the collision of generated ions, radicals or additionally gas molecules causes breaking and disappearance of the etch residue 21 as described above, yet ions and radicals generated by realizing a plasma state hardly causes etching of the surface of the semiconductor substrate 1. That is, the surface uneven structure 2 can be formed in the residue removing step without breaking the projection portion 23 formed in the roughening step and damaging the surface of the semiconductor substrate 1.

This may be because energy of ions, radicals and gas molecules is sufficient for breaking the pillar portion 22 in the etch residue 21 but yet insufficient for damaging the surface of the semiconductor substrate 1. This means that removal of the residue by lower impact force than a case of conventionally removing the etch residue with the use of ultrasonic treatment is realized.

The conditions for converting the second gas into a plasma state in the residue removing step are preferably determined so that the best residue removing effect is obtained in accordance with kinds of the second gas and capacity of the chamber. Needless to say, however, the gas flow rate varies with capacity of the chamber to be used, and the conditions vary with kinds of gas for treating and equipment, so that it is difficult to prescribe univocally. Yet, for example, when oxygen is used as the second gas, the standard can be such that reaction pressure with the semiconductor substrate 1 in the chamber is 10 to 40 Pa, RF electric power is 1000 to 2000 W and treating time is 5 to 60 sec.

FIG. 3C is a view showing state after performing hydrofluoric acid treatment following the removal of the etch residue by the residue removing step. As described above, with regard to the semiconductor substrate 1 subjected to the residue removing step, the surface thereof is so hardly damaged that no cracks and chips are caused on the surface even after performing hydrofluoric acid treatment.

That is to say, in the embodiments, the etch residue 21 can be removed while restraining damage such as cracks from being caused on the surface unlike a case of conventional ultrasonic treatment.

For example, even in a case of being thinned to 200 μm or less, the semiconductor substrate 1 can sufficiently resist the residue removing step.

Equipment for use in the residue removing step is not particularly limited if the equipment is capable of converting the second gas into a plasma state in the presence of the semiconductor substrate 1 to make ions, radicals and gas molecules thereof collide with the semiconductor substrate 1. For example, reactive ion etching equipment to be used for the roughening step can be utilized for the residue removing step.

In a case of using the reactive ion etching equipment 100 shown in FIG. 2, oxygen (O₂) and nitrogen (N₂) are supplied at a flow ratio of 5:1 to the semiconductor substrate 1 subjected to the roughening step, which is disposed in the chamber 17, by using the above-mentioned mass flow controller 11, with being regulated by the pressure regulator 13 so as to be a predetermined pressure.

Thereafter, RF electric power is impressed from the RF power supply 15 on the RF electrode 12 to generate plasma state in the chamber 17 by exciting and decomposing at least the second gas. The etch residue 21 remaining on the semiconductor substrate 1 is removed due to the collision of generated ions and radicals.

Preferably, the roughening step and the residue removing step are performed sequentially in the same chamber. The decrease of the step of conveying the semiconductor substrate 1 every time the step is finished contributes to restraint of manufacturing costs of a solar cell element. The semiconductor substrate need not be taken out of the chamber between the roughening step and the residue removing step, so that cracks and chips of the semiconductor substrate due to handling mistakes can be prevented.

Further, in a case of performing the roughening step and the residue removing step in the same chamber, the decompressing step of vacuuming the inside of the chamber is preferably included between the roughening step and the residue removing step.

Thus, the inside of the chamber can be filled with the second gas, after the first gas used in the roughening step has been removed from the inside of the chamber. This can prevent the semiconductor substrate 1 from being etched more than required by the first gas remaining in the chamber at the residue removing step. Accordingly, the fine projection portion once formed can be restrained from being broken.

The second gas preferably includes inert gas.

Here, inert gas is defined as the gas consisting such elements as helium (He), neon (Ne), argon (Ar), krypton (Kr), xenon (Xe) and radon (Rn), belonging to the group 18.

The reason therefor is that an atom composing inert gas is so chemically inert as to offer no etching action on the semiconductor substrate 1 and no action as impurities against the semiconductor substrate 1 but have only the action of removing the etch residue 21.

Here, a case of using nitrogen gas, as one kind of inert gas, for the second gas is taken as an example for description.

After the roughening step, nitrogen gas is supplied as the second gas to the inside of the chamber once through the decompressing step of vacuuming gas inside the chamber. Then, RF electric power is impressed from the RF power supply 15 on the RF electrode 12 to form nitrogen plasma, which is so-called nonequilibrium plasma, high in electron temperature as compared with gas temperature. The etch residue 21 is removed by forming such a state of nitrogen plasma to cause plasma discharge for a certain time with active species such as nitrogen molecules, nitrogen ions and nitrogen radicals.

The etch residue removal by nitrogen plasma is lower in reactivity with the semiconductor substrate 1 than a case of using fluorine-based etching gas, so that the etch residue 21 can be removed without damaging the semiconductor substrate 1 while retaining the minute projection portion 23.

Here, low reactivity with the semiconductor substrate 1 means that nitrogen offers the etching action on the semiconductor substrate 1 with difficulty. Accordingly, it is conceived that the etch residue 21 is removed by collision of plasma species such as nitrogen molecules, nitrogen ions and nitrogen radicals. Inert gas is far safe, inexpensive, and stable gas as compared with fluorine-based etching gas, requires neither special handling, safety devices nor harm removal equipment, and has no bad influence on the environment. Therefore, the etch residue removal can be performed at low costs without decreasing productivity.

The second gas according to the present invention preferably includes oxygen gas.

Even in a case once through the decompressing step of vacuuming gas inside the chamber after the roughening step, there is a possibility that the first gas resides in the projection portion 23 (and the etch residue 21) of the semiconductor substrate 1 when the semiconductor substrate 1 is taken out of the chamber.

Fluorine-based and chlorine-based gas with strong etching action is used for the first gas, which is thereby frequently harmful gas to the human body and can be a problem in work. However, oxygen gas as the second gas is converted into a plasma state in the residue removing step after the roughening step, so that not merely the etch residue 21 is removed but also the first gas residing in the projection portion 23 (and the etch residue 21) is removed, leading to harmlessness. The reason therefor is conceived to be that oxygen molecules, oxygen ions and oxygen radicals have the function of adsorbing the first gas as residual gas.

As described above, according to a manufacturing method of a solar cell element involved in the embodiments, the etch residue can be removed from the surface of the semiconductor substrate without causing microcracks in a projection portion formed at the roughening step to form the surface uneven structure. Thus, cracks and chips are restrained from occurring on the surface of the semiconductor substrate in accordance with removal of the etch residue. The etch residue is so preferably removed as to be capable of restraining a deterioration in conversion efficiency of a solar cell element for the reason that incident light is shielded by the etch residue to shade a receiving surface. That is, according to a manufacturing method of a solar cell element involved in the embodiments, the removal can restrain a deterioration in properties of a solar cell element due to damage to the semiconductor substrate, and additionally improve the yield of a solar cell element.

In addition, according to a manufacturing method of a solar cell element involved in the embodiments, unevenness is caused with difficulty in forming an antireflection film on the surface uneven structure of the semiconductor substrate. The reason therefor is that because the etch residue produced at the roughening step is preferably removed at the residue removing step, the etch residue is sufficiently removed as compared with the residue after the roughening step, even if it remains after the residue removing step.

The embodiments of the present invention are not limited to only the above-mentioned examples but it is needless to say that various modifications can be made within a range of not deviating from the scope of the present invention.

For example, the washing step for cleansing the surface of the semiconductor substrate 1 may be performed for a post-process of the semiconductor substrate 1 obtained as described above. The performance of the washing step allows a semiconductor junction layer to be formed on a clean surface at the step of forming a reverse conducting semiconductor as another post-process thereof, being preferable by reason of improving properties of a solar cell element.

It is desirable that this washing step be wet etching treatment with solution including hydrofluoric acid, such as 0.1 to 50% by weight-aqueous solution of hydrofluoric acid, or mixed acid (such as a mixture of hydrofluoric acid and nitric acid at a ratio of 1:10). Thus, it is more preferable for the reason that the use of solution including hydrofluoric acid at the washing step allows also the etch residue not removed up particularly by the residue removing step to be removed.

The above-mentioned description offers an example such that the back impurity diffusion layer 4 (BSF) is formed on the back side of the semiconductor substrate 1 after the front impurity diffusion layer 3 is formed on the semiconductor substrate 1, and the embodiment of forming the back impurity diffusion layer 4 is not limited thereto. For example, film formation may be performed so that substrate temperature is approximately 400° C. or less and film thickness is approximately 10 to 200 nm while doping a hydrogenated amorphous silicon film and a crystalline silicon film including a microcrystalline silicon phase with impurities by plasma CVD method so as to be in high concentration. Thus, in a case of film formation with the use of vacuum process, it is desirable to compose the equipment so that film formation can successively be performed without opening to the air on the way. That case brings an advantage that a solar cell element of high quality can be formed without forming a natural oxide film on the surface irregular structure 2 and contaminating the semiconductor substrate 1 with unintended impurities at the step on the way.

While the invention has been shown and described in detail, the foregoing description is in all aspects illustrative and not restrictive. It is therefore understood that numerous modifications and variations can be devised without departing from the scope of the invention.

What is claimed is:

1. A manufacturing method of a solar cell element comprising the following steps of:
(a) disposing a base substance for a solar cell element inside a first chamber and then supplying a first gas to etch one principal surface of said base substance, thereby roughening said one principal surface while attaching an etch residue thereto; and
(b) disposing said base substance inside a second chamber and then supplying a second gas having lower reactivity than said first gas to convert said second gas into a plasma state, thereby removing said etch residue remaining on said one principal surface.

2. The manufacturing method of a solar cell element according to claim 1, wherein
a same chamber is used for said first chamber and said second chamber.

3. The manufacturing method of a solar cell element according to claim 2 further comprising the following step of:
(c) vacuuming an inside of said chamber, said step (c) being performed between said step (a) and said step (b).

4. The manufacturing method of a solar cell element according to claim 1, wherein
said step (a) is performed by reactive ion etching.

5. The manufacturing method of a solar cell element according to claim 1, wherein
said second gas comprises at least one kind of element among elements belonging to the groups 1 to 16 and 18.

6. The manufacturing method of a solar cell element according to claim 5, wherein
said second gas includes inert gas.

7. The manufacturing method of a solar cell element according to claim 5, wherein
said second gas includes oxygen.

8. A method of manufacturing a solar cell element, comprising the steps of:
preparing a base substance for a solar cell element;
disposing said base substance inside a first chamber;
etching one principal surface of said base substance by reactive ion etching using a first gas inside said first chamber;
disposing said base substance inside a second chamber after said step of etching said one principal surface of said base substance;
supplying a second gas having lower reactivity than said first gas into said second chamber; and
converting said second gas into a plasma state to remove etch residue by collisional breakage, said etch residue being left on said one principal surface by said step of etching said one principal surface of said base substance.
